(19) United States
(12) Patent Application Publication
(10) Pub. No.: US 2007/0030654 A1
(43) Pub. Date: Feb. 8, 2007

(54) Heat dissipation modules and assembling methods thereof

(75) Inventors: Cheng-Chih Lee, Taoyuan Hsien (TW); Chi-Feng Lin, Taoyuan Hsien (TW); Chin-Ming Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/368,381

(22) Filed: Mar. 7, 2006

(30) Foreign Application Priority Data
Aug. 4, 2005 (TW) 94126514

(51) Int. Cl. H05K 7/20

(52) U.S. Cl. 361/707

(57) ABSTRACT

A heat dissipation module includes a heat pipe and at least one thermal conductor. Each of the thermal conductors includes an opening for allowing the heat pipe to pass therethrough. A joining portion extends from an edge of the opening of each of the thermal conductors. The joining portion has a cavity for receiving a solder material. A solder material is disposed in the cavity, and the heat pipe is inserted through the openings. The heat pipe and the thermal conductors are turned over in the reflow process, such that the heat pipe and the thermal conductors are perfectly connected. An assembling method of the heat dissipation module is further provided.

This Non-provisional Application claims priority under U.S.C. § 119(a) on Patent Application No(s). 094126514, filed in Taiwan, Republic of China on Aug. 4, 2005, the entire contents of which are hereby incorporated by reference.

### BACKGROUND OF THE INVENTION

1. Field of the Invention

The invention relates in general to heat dissipation modules and in particular to heat dissipation modules with high heat dissipation efficiency.

2. Description of the Related Art

With progress in IC fabrication, while the number of transistors per unit area within an electronic component has greatly increased, more heat is generated during its operation. Moreover, with respect to high speed on/off operation of the transistors, heat can also be generated from switch loss of the transistors. Heat accumulation may adversely affect processing speed and life of transistors. To prevent heat accumulation within electronic components, conventional cooling apparatuses are provided to dissipate heat through fins by free or forced convection.

Conventionally, heat pipes have a small cross section, capable of heat transmission over a long distance without power supply. Since heat pipes have small dimensions and are economic to produce, they have been widely used in various electronic products for heat dissipation. As cited in Taiwan patent No. 332,681, several aluminum fins are mounted on a heat pipe in order to increase heat dissipation area. However, as the fins and the heat pipe are joined by press-fitting, effective seals are hard to achieve. If the fins and the heat pipe are fitted too tight, it may lead to damage of the heat pipe. If the fins and the heat pipe are fitted too loose, the fins may be separated with respect to the heat pipe. Both situations may adversely affect cooling efficiency.

Referring to FIGS. 1A and 1B, FIG. 1A is a perspective diagram of a conventional heat dissipation module having a heat pipe and a plurality of fins connected thereto, and FIG. 1B is a large view of portion “A” in FIG. 1A. As shown in FIG. 1A, the conventional heat dissipation module 100a has a U-shaped heat pipe 110 and several fins 120, wherein the heat pipe 110 has wick structures. The heat dissipation module 100a can transfer heat from a heat source to the fins 120 via the U-shaped heat pipe 110, and then dissipate heat through the fins 120 by convection.

As shown in FIG. 1B, each of the fins 120 has an opening 121 for allowing the heat pipe 110 to pass therethrough. An annular joining portion 122 is extended and projects from a lateral side of each of the fins 120, where is close to the opening 121. Specifically, an orifice 123 is formed on the top side of the joining portion 122 (on the upper side of the opening 141). After the heat pipe 110 pass through the fins 120, a solder material is put in the space where the orifice 123 is located by injection along the direction “X” shown in FIG. 1B, so that the heat pipe 110 and the fins 120 are jointed associating with the adhesion of the solder material. However, such assembly way is complex and inconvenient to mass production. Moreover, incomplete soldering may occur because the protrusive joining portion 122 can obstruct the solder material flow to desired soldering areas, adversely affecting cooling efficiency.

Referring to FIGS. 1C and 1D, FIG. 1C is a perspective diagram of another conventional heat dissipation module having a heat pipe and a plurality of fins connected thereto, and FIG. 1D is a large view of portion “B” in FIG. 1C, heat dissipation module 100b has a U-shaped heat pipe 130 and several fins 140, wherein the heat pipe 130 has wick structures. The heat dissipation module 100b transfers heat from a heat source to the fins 140 via the U-shaped heat pipe 130, and dissipates heat through the fins 140 by convection.

As shown in FIG. 1D,each of the fins 140 has an opening 141 for allowing the heat pipe 130 to pass therethrough. A non-enclosed annular joining portion 142 is extended and projects from a lateral side of each of the fins 140, where is close to the opening 141, and a longitudinal slot 143 vertically extends from the top of the joining portion 142, i.e. the longitudinal slot 143 is vertically located on the upper side of the opening 141. After the heat pipe 130 pass through the fins 140, a solder material is put in the space where the longitudinal slot 143 is located by injection along the direction “Y” shown in FIG. 1D. Subsequently, the heat pipe 130 and the fins 140 are turned over and sent into the oven for performing a curing procedure, such that the melted solder material spreads to the periphery of the heat pipe 130 by gravity.

However, since the two longitudinal slots 143 are extended in opposite directions on the fins 140, the solder material can flow only in one direction to spread by gravity. Thus, the solder material is difficult to evenly distribute. To solve the problem, solder injection, curing and turning over the heat pipe 130 and the fins 140 must be repeated for even distribution of the solder material. Such assembly is also complex and inconvenient for mass production. Moreover, the longitudinal slots 143 on the fins 140 occupy heat dissipation area, so that the entire cooling efficiency is decreased.

### BRIEF SUMMARY OF THE INVENTION

Thus, a heat dissipation module is provided that is simple to assemble, easy to practice and suitable for mass productions, in which the solder material is prevented from leakage during the reflow process, facilitating high cooling efficiency and providing a tidy appearance of the heat dissipation module.

The invention provides a heat dissipation module including a heat pipe and at least one thermal conductor. Each of the thermal conductors includes an opening for allowing the heat pipe to pass therethrough. A joining portion projects from an edge of the opening and surrounds the opening,. The joining portion is formed with a convex cavity to receive a solder material.

In some embodiments, the joining portion has a substantially closed ring shape, and projects from a side of the thermal conductor. Further, the joining portion has a cross section with a circular, elliptical, half-circular, rectangular, triangular, quadrilateral, trapezoid, equilateral or inequilateral shape. The thermal conductor can be a heat-dissipating fin, heat-conducting plate or any other thermal conductive component. Moreover, the thermal conductors can be horizontally, vertically, obliquely or radially arranged.

In some embodiments, the heat pipe is U-shaped, and the solder material can be soldering paste, thermal grease or any other thermal conductive material. The heat pipe is directly or indirectly connected to a heat source, transferring heat therefrom to the thermal conductors.

In some embodiments, the heat pipe includes a wick structure including plastic, metal, alloy or nonmetallic porous materials. The wick structure is a mesh, fiber, sinter or groove structure. Moreover, the wick structure is formed on an inner surface of the heat pipe by way of sintering, adhesive, filling or deposition.

In some embodiments, a working medium is disposed in the heat pipe for heat transmission, of inorganic compound, water, alcohol, liquid metal, ketone, Freon, or organic compound.

The invention further provides an assembling method for a heat dissipation module. First, a heat pipe and at least one thermal conductor are provided. Each of the thermal conductors has an opening. A joining portion projects from an edge of the opening and surrounds the opening. Also, the joining portion is formed with a convex cavity to receive a solder material. Subsequently, a solder material is disposed in the cavity, and the heat pipe is inserted through the openings. Finally, the heat pipe and the thermal conductors are turned over in the reflow process.

In some embodiments, the joining portion has a substantially closed ring shape, and projects from a side of the thermal conductor. The joining portion has a cross section with a circular, elliptical, half-circular, rectangular, triangular, quadrilateral, trapezoid, equilateral or inequilateral shape. The thermal conductor can be a heat-dissipating fin, heat-conducting plate or any other thermal conductive component. Moreover, the thermal conductors can be horizontally, vertically, obliquely or radially arranged. In some embodiments, the heat pipe is U-shaped, and the solder material can be a soldering paste, thermal grease or any other thermal conductive materials.

### BRIEF DESCRIPTION OF THE DRAWINGS

The invention can be more fully understood by reading the subsequent detailed description and examples with references made to the accompanying drawings, wherein:

FIG. 1A is a perspective diagram of a conventional assembly of a heat pipe and fins;

FIG. 1B is a large view of portion “A” in FIG. 1A;

FIG. 1C is a perspective diagram of another conventional assembly of a heat pipe and fins;

FIG. 1D is a large view of portion “B” in FIG. 1C;

FIG. 2A is an exploded diagram of an embodiment of a heat dissipation module;

FIG. 2B is a large view of portion “C” in FIG. 2A;

FIG. 3A is a perspective diagram of the heat dissipation module in FIG. 2A after assembling; and

FIG. 3B is a large view of portion “D” in FIG. 3A.

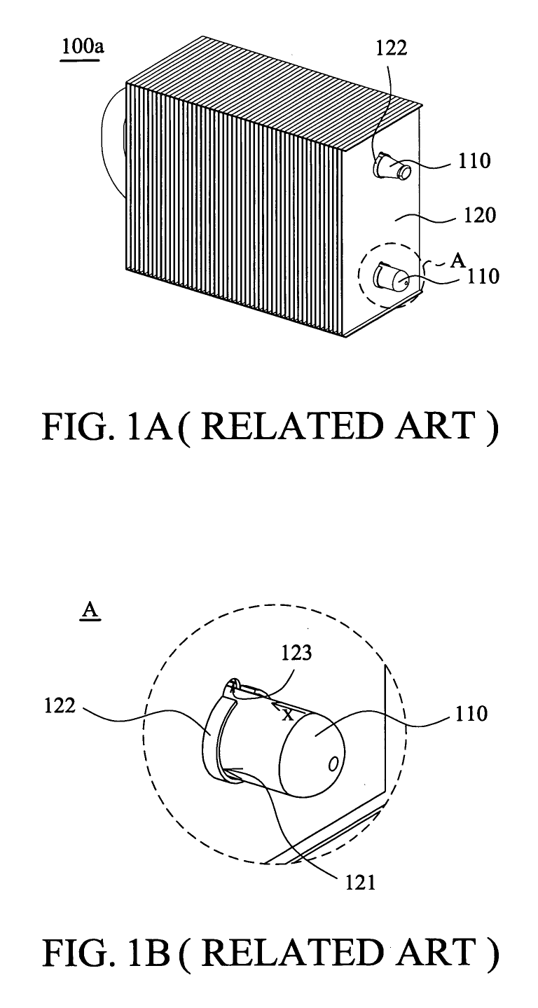

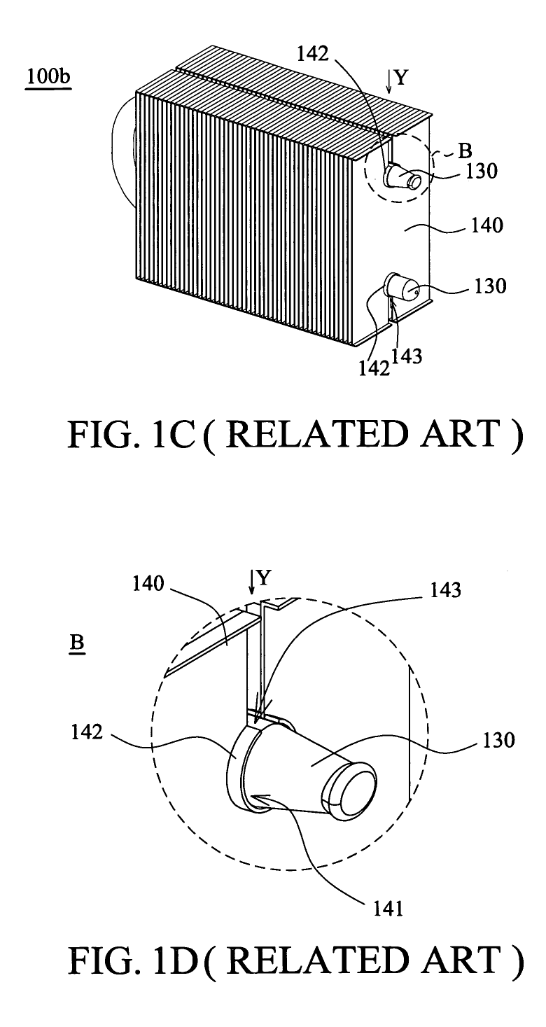

### DETAILED DESCRIPTION OF THE INVENTION

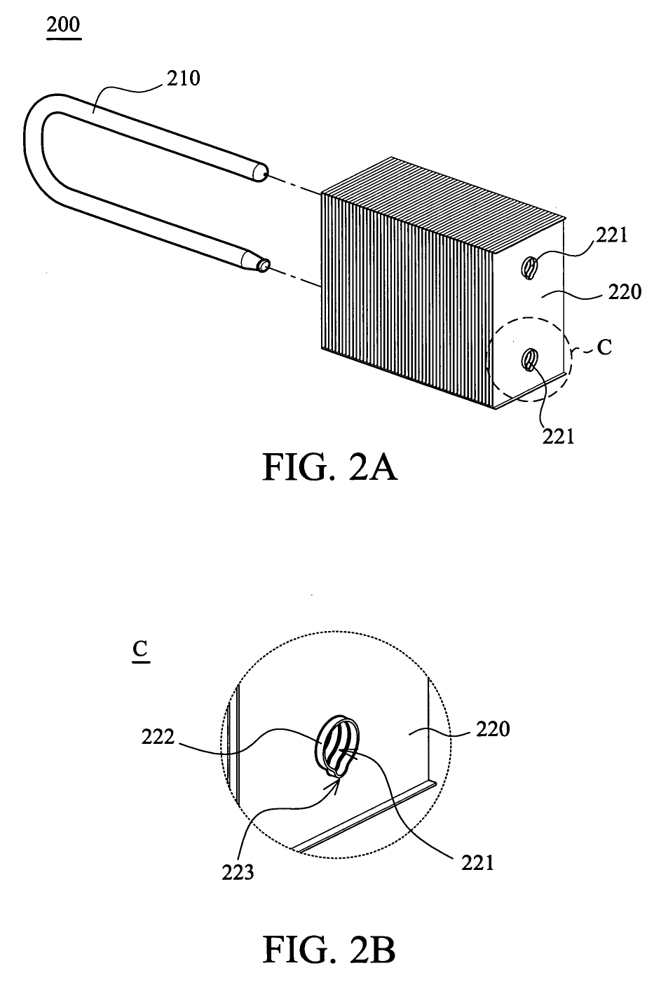

FIG. 2A is a perspective diagram of an embodiment of a heat dissipation module, and FIG. 2B is a large view of portion C in FIG. 2A. As shown in FIG. 2A, an embodiment of a heat dissipation module 200 includes a U-shaped heat pipe 210 and a plurality of thermal conductors 220. The heat pipe 210 directly or indirectly connects a heat source, transferring heat from the heat source to the thermal conductors 220. Then, heat is rapidly dissipated by convection, such as forced convection from a cooling fan. In some embodiments, the heat source can be an electronic component generating heat.

In some embodiments, the thermal conductors 220 can be heat-dissipating fins, heat-conducting plates or any other thermal conductive components. The thermal conductors 220 are arranged horizontally, vertically, obliquely, radially or in other formations.

The U-shaped heat pipe 210 has a wick structure disposed on an inner surface of the heat pipe 210, such as copper, aluminum, iron, metal/alloy or nonmetallic porous material. The wick structure is a mesh, fiber, sinter or groove structure. In some embodiments, the wick structure is disposed on the inner surface of the heat pipe by way of sintering, adhesive, filling and/or deposition. Further, a working medium is disposed in the heat pipe for heat transmission, such as inorganic compound, water, alcohol, liquid metal, ketone, Freon or organic compound.

Each of the thermal conductors 220 has at least one opening 221 for allowing the heat pipe 210 to pass therethrough. Specifically, the joining portion 222 has a substantially closed ring shape, and projects from a side of the thermal conductor 220. A convex cavity 223 is formed at the lower side of the joining portion 222 and the opening 221, to receive a solder material. The solder material, such as a soldering paste, thermal grease or any other thermal conductive materials, provides smooth connection between the heat pipe 210 and the thermal conductors 220, thereby enhancing thermal transmission of the heat dissipation module 200.

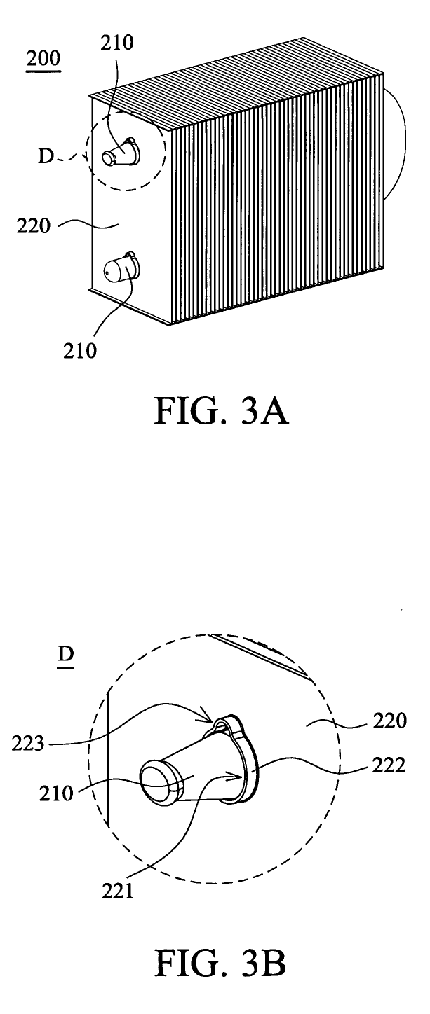

Referring to FIGS. 3A and 3B, FIG. 3A is a perspective diagram of the heat dissipation module 200 in FIG. 2A after assembly, and FIG. 3B is a large view of portion “D” in FIG. 3A. When a solder material is disposed in the cavity 223, the heat pipe 210 is inserted through the openings 221 of the thermal conductors 220. Next, the heat pipe 210 and the thermal conductors 220 are turned upside down and cured in a furnace in the reflow process, as shown in FIG. 3A and 3B. Hence, the cavity 223 is situated on the top side of the joining portion 222, such that melting solder material spreads evenly to the periphery of the heat pipe 210 by gravity, adjacent to the joining portion 222 and the openings 221. Finally, the heat pipe 210, surrounded by the solder material, perfectly connects the heat pipe 210 and the thermal conductors 220. It is noted that the solder material is omitted from FIGS. 3A and 3B, to clearly depict the heat pipe 210, the joining portion 222 and the cavity 223.

In addition to the approximately circular cross-section of the joining portion 222 shown in FIGS. 2A, 2B, 3A and 3B, the joining portion 222 can has a cross section with a elliptical, half-circular, rectangular, triangular, quadrilateral, trapezoid, equilateral or inequilateral shape for appropriate connection of the heat pipe 210 and the thermal conductors 220, to facilitate superior thermal transmission.

As shown in FIGS. 2A, 2B, 3A and 3B, an assembling method of a heat dissipation module is further provided. First, a heat pipe 210 and at least one thermal conductor 220 are provided. Each of the thermal conductors 220 has an opening 221. A joining portion 222 projects from an edge of the opening 221 and surrounds the opening 221. Also, the joining portion 222 is formed with a convex cavity 223 to receive a solder material. Subsequently, a solder material is disposed in the cavity 223, and the heat pipe 210 is inserted through the openings 221. Finally, the heat pipe 210 and the thermal conductors 220 are turned over in the reflow process.

When solder material is disposed in the cavity 223, the heat pipe 210 and the thermal conductors 220 are cured in a furnace upside down in the reflow process. Hence, melting solder material evenly spreads to the periphery of the heat pipe 210 by gravity, adjacent to the joining portion 222 and the openings 221. Finally, the heat pipe 210 is surrounded by the solder material to perfectly connect the heat pipe 210 and the thermal conductors 220, enhancing thermal transmission of the heat dissipation module 200.

Compared with conventional assemblies of heat dissipation modules, the invention is simpler and easier to practice, and more suitable for mass production. In some embodiments, the convex cavity 223 is integrally formed with the joining portion 222, preventing incomplete soldering and obstruction of solder flow by protrusive joining portion 222, facilitating heat dissipation efficiency. As the solder material is previously received in the cavity 223, the heat pipe 210 maintains the solder in the cavity 223 when being inserted through the opening 221, such that the heat pipe 210 can be fully surrounded by the solder. Moreover, since thermal conductors 220 are closely arranged at small intervals, the solder is preserved from leakage during the reflow process, thereby providing a tidy appearance of the heat dissipation module 200.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A heat dissipation module, comprising:
a heat pipe; and
at least one thermal conductor, each of which comprises an opening for allowing the heat pipe to pass therethrough, and a joining portion extending from an edge of the opening and surrounding the opening, wherein the joining portion is formed with a cavity to receive a solder material.

2. The heat dissipation module as claimed in claim 1, wherein the joining portion has a substantially closed ring shape, and projects from a side of the thermal conductor.

3. The heat dissipation module as claimed in claim 1, wherein the joining portion has a cross section with a circular, elliptical, half-circular, rectangular, triangular, quadrilateral, trapezoid, equilateral or inequilateral shape.

4. The heat dissipation module as claimed in claim 1, wherein the solder material comprises a soldering paste, thermal grease or any other thermal conductive materials.

5. The heat dissipation module as claimed in claim 1, wherein the thermal conductor comprises a heat-dissipating fin, heat-conducting plate or any other thermal conductive components.

6. The heat dissipation module as claimed in claim 1, wherein the heat pipe is U-shaped.

7. The heat dissipation module as claimed in claim 1, wherein the heat pipe directly connects a heat source or connects the heat source via a base, to transmit heat from the heat source to the thermal conductor.

8. The heat dissipation module as claimed in claim 1, wherein the heat pipe comprises a wick structure disposed on an inner surface of the heat pipe.

9. The heat dissipation module as claimed in claim 8, wherein the wick structure is a mesh, fiber, sinter or groove structure.

10. The heat dissipation module as claimed in claim 8, wherein the wick structure is disposed on the inner surface of the heat pipe by way of sintering, adhesive, filling or deposition.

11. An assembling method of a heat dissipation module, comprising:
providing a heat pipe and at least one thermal conductor, each of which comprises an opening, and a joining portion extending from an edge of the opening and surrounding the opening, wherein the joining portion is formed with a cavity;
disposing a solder material in the cavity of the joining portion;
inserting the heat pipe into the thermal conductors by respectively passing through the openings of the thermal conductors;
turning over the heat pipe and the thermal conductors; and
performing a reflowing process.

12. The assembling method as claimed in claim 11, wherein the joining portion has a substantially closed ring shape, and projects from a side of the thermal conductor.

13. The assembling method as claimed in claim 11, wherein the joining portion has a cross section with a circular, elliptical, half-circular, rectangular, triangular, quadrilateral, trapezoid, equilateral or inequilateral shape.

14. The assembling method as claimed in claim 11, wherein the solder material comprises a soldering paste, thermal grease or any other thermal conductive materials.

15. The assembling method as claimed in claim 11, wherein the thermal conductor comprises a heat-dissipating fin, heat-conducting plate or any other thermal conductive component.

16. The assembling method as claimed in claim 11, wherein the heat pipe is U-shaped.

17. The assembling method as claimed in claim 11, wherein the heat pipe directly connects a heat source or connects the heat source via a base, to transmit heat from the heat source to the thermal conductor.

18. The assembling method as claimed in claim 11, wherein the heat pipe comprises a wick structure disposed on an inner surface of the heat pipe.

19. The assembling method as claimed in claim 18, wherein the wick structure is a mesh, fiber, sinter or groove structure.

20. The assembling method as claimed in claim 18, wherein the wick structure is disposed on the inner surface of the heat pipe by way of sintering, adhesive, filling or deposition.
